(19) United States
(12) Patent Application Publication
(10) Pub. No.: US 2015/0194395 A1
(43) Pub. Date: Jul. 9, 2015

(54) BOND PAD HAVING A TRENCH AND METHOD FOR FORMING

(71) Applicants: Sohrab Safai, Austin, TX (US); David B. Clegg, Austin, TX (US); Tu-Anh N. Tran, Austin, TX (US)

(72) Inventors: Sohrab Safai, Austin, TX (US); David B. Clegg, Austin, TX (US); Tu-Anh N. Tran, Austin, TX (US)

(21) Appl. No.: 14/147,234

(22) Filed: Jan. 3, 2014

(51) Int. Cl. H01L 23/00

(52) U.S. Cl. CPC H01L 24/03; H01L 24/85; H01L 24/08; H01L 2224/03831; H01L 2924/01029; H01L 2924/01013; H01L 2224/85031

(57) ABSTRACT

A method includes forming a conductive bond pad over a conductive structure in a last metal layer of an integrated circuit. A trench is etched around at least a portion of a perimeter of a wire bond region of the conductive bond pad. A portion of the conductive bond pad remains at the bottom of the trench to retain a conductive path between the wire bond pad region and the integrated circuit. The trench is positioned and sized to contain at least a portion of a splash of the conductive bond pad when a wire bond is subsequently formed in the wire bond region.

### BACKGROUND

1. Field

This disclosure relates generally to semiconductor processing, and more specifically, to forming a bond pad having a trench.

2. Related Art

Wire bonds provide electric connections to underlying circuitry within a semiconductor device. The ball bond of a wire bond is attached to a bond pad formed on the semiconductor device. For example, copper is commonly used for the wire bond and aluminum is commonly used as the bond pad. The bond pads of a semiconductor device are physically separated from each other, and the spaces between adjacent bond pads typically include passivation. However, during the bonding process, when the ball bond of the wire bond is attached to the aluminum bond pad, the aluminum pad deforms resulting in an aluminum splash which extends from under the ball bond. This aluminum splash may result in passivation cracking. The cracks in passivation may result in reliability failures of the semiconductor device.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIG. 1 illustrates a cross-sectional view of a semiconductor structure at a stage of processing in accordance with an embodiment of the present invention.

FIG. 2 illustrates a cross-sectional view of the semiconductor structure of FIG. 1 at a subsequent stage of processing in accordance with an embodiment of the present invention.

FIG. 3 illustrates a cross-sectional view of the semiconductor structure of FIG. 2 at a subsequent stage of processing in accordance with an embodiment of the present invention.

FIG. 4 illustrates a cross-sectional view of the semiconductor structure of FIG. 3 at a subsequent stage of processing in accordance with an embodiment of the present invention.

FIG. 5 illustrates a cross-sectional view of the semiconductor structure of FIG. 4 at a subsequent stage of processing in accordance with an embodiment of the present invention.

FIG. 6 illustrates a cross-sectional view of the semiconductor structure of FIG. 5 at a subsequent stage of processing in accordance with an embodiment of the present invention.

FIG. 7 illustrates a cross-sectional view of the semiconductor structure of FIG. 6 at a subsequent stage of processing in accordance with an embodiment of the present invention.

FIG. 8 illustrates a cross-sectional view of the semiconductor structure of FIG. 7 at a subsequent stage of processing in accordance with an embodiment of the present invention.

FIG. 9 illustrates a top-down view of the semiconductor structure of FIG. 8, in accordance with an embodiment of the present invention.

FIG. 10 illustrates a top-down view of a semiconductor structure in accordance with another embodiment of the present invention.

FIG. 11 illustrates a top-down view of a semiconductor structure in accordance with another embodiment of the present invention.

FIGS. 12-13 illustrate cross-sectional views of an example wire bonding sequence, in accordance with one embodiment of the present invention.

### DETAILED DESCRIPTION

During wire bonding, a conductive splash forms when the ball bond of a wire bond is attached onto a bond pad of a semiconductor device. The majority of this conductive splash is typically formed in the direction of the ultrasonic vibration of the wire bonder's transducer. In one embodiment, a trench is formed in the bond pad which is positioned and sized to contain at least a portion of the splash. This trench is formed by performing a patterned partial etch into the bond pad such that the trench does not extend through the entire thickness of the bond pad.

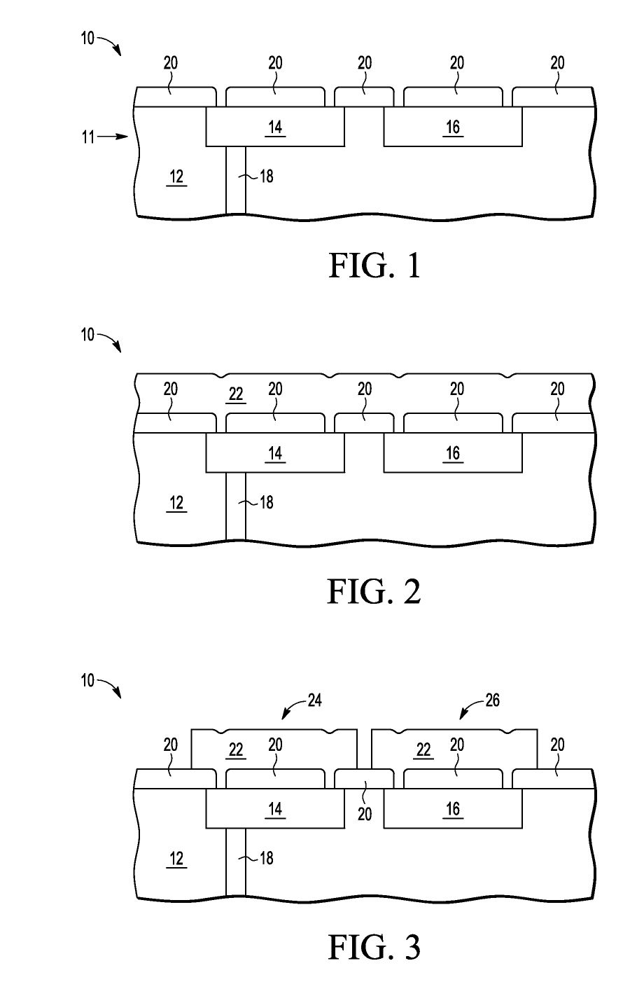

FIG. 1 illustrates, in a cross-sectional view, a semiconductor structure 10 (also referred to as an integrated circuit) which includes a last metal layer 11 formed within an interlayer dielectric layer (ILD) 12. Although not illustrated in FIG. 1, semiconductor structure 10 includes active circuitry formed on and in a semiconductor substrate and having a plurality of interconnect layers formed over the active circuitry. Each interconnect layer may include interlayer conductive portions (e.g. to route signals within a layer) and intralayer conductive portions (e.g. to route signals between layers). Last metal layer 11 corresponds to the last metal layer of the interconnect layers. Last metal layer includes conductive structures 14 and 16. Semiconductor structure 10 also includes a conductive via 18 which extends from conductive structure 14 to an underlying interconnect layer. Conductive via 18, which corresponds to an interlayer conductive portion, may be considered as part of last metal layer 11. Note that the interconnect layers provide electrical connections between the conductive structures of last metal layer 11, such as conductive structures 14 and 16, to the underlying active circuitry. Semiconductor structure 10 also includes a passivation layer 20 formed over last metal layer 11. Passivation layer 20 includes openings which exposes potions of underlying conductive structures 14 and 16.

FIG. 2 illustrates, in a cross-sectional view, semiconductor structure 10 after formation of a conductive layer 22 over passivation layer 20. In one embodiment, conductive layer 22 is blanket deposited over passivation layer 20. Conductive layer 22 includes a conductive material, such as aluminum. Therefore, in one embodiment, conductive layer 22 is an aluminum layer.

FIG. 3 illustrates, in a cross-sectional view, semiconductor structure 10 after patterning of conductive layer 22 to form a bond pad 24 which directly contacts conductive structure 14 through the openings of passivation layer 20 over conductive structure 14 and a bond pad 26 which directly contacts conductive structure 16 through the openings of passivation layer 20 over conductive structure 16. Bond pads 24 and 26 are physically separate from each other and each will be capable of receiving an external connection, such as a wire bond connection. Note that any number of bond pads may be formed from conductive layer 22 over passivation layer 20 in which each bond pad may be in physical contact with an underlying conductive portion of last metal layer 11. The bond pads, such as bond pads 24 and 26, allow for external connections to be made to structure 10, such as with wire bonds, and may therefore also be referred to as external bond pads.

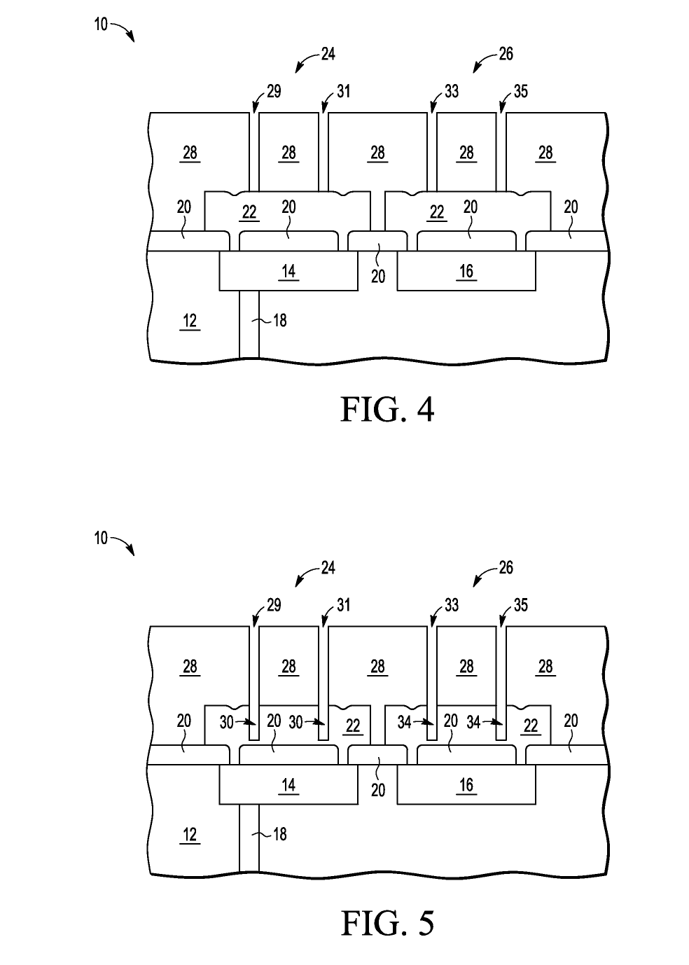

FIG. 4 illustrates, in a cross-sectional view, semiconductor structure 10 after formation of a patterned photo resist layer 28 formed over passivation layer 20 and patterned conductive layer 22. In one embodiment, a photo resist layer is blanket deposited and then patterned to form openings 29, 31, 33, and 35. These openings correspond to locations of one or more trenches which will be formed in each of underlying bond pads 24 and 26.

FIG. 5 illustrates, in a cross-sectional view, semiconductor structure 10 after openings 29, 31, 33, and 35 are extended into underlying conductive layer 22 to form a trench 30 in bond pad 24 and a trench 34 in bond pad 26. That is, openings 29 and 31 correspond to opposite sides of a single opening which extends into bond pad 24 to form trench 30 and openings 33 and 35 correspond to opposite sides of a single opening which extends into bond pad 26 to form trench 34. In one embodiment, a partial etch is performed such that trench 30 only extends partially through bond pad 24 and trench 34 only extends partially through bond pad 26. That is, trenches 30 and 34 do not extend an entire thickness of conductive layer 22. In one embodiment, trench 30 is formed around a wire bond region of pad 24, and trench 34 is formed around a wire bond region of pad 36. A wire bond region of a bond pad is a region which is designed to receive a wire bond connection. Note that a portion of bond pad 24 remains at the bottom of trench 30 to retain a conductive path between the wire bond region of bond pad 24 and conductive structure 14. Similarly, a portion of bond pad 26 remains at the bottom of trench 34 to retain a conductive path between the wire bond region of bond pad 26 and conductive structure 16. This will be illustrated in further detail in a top down view below.

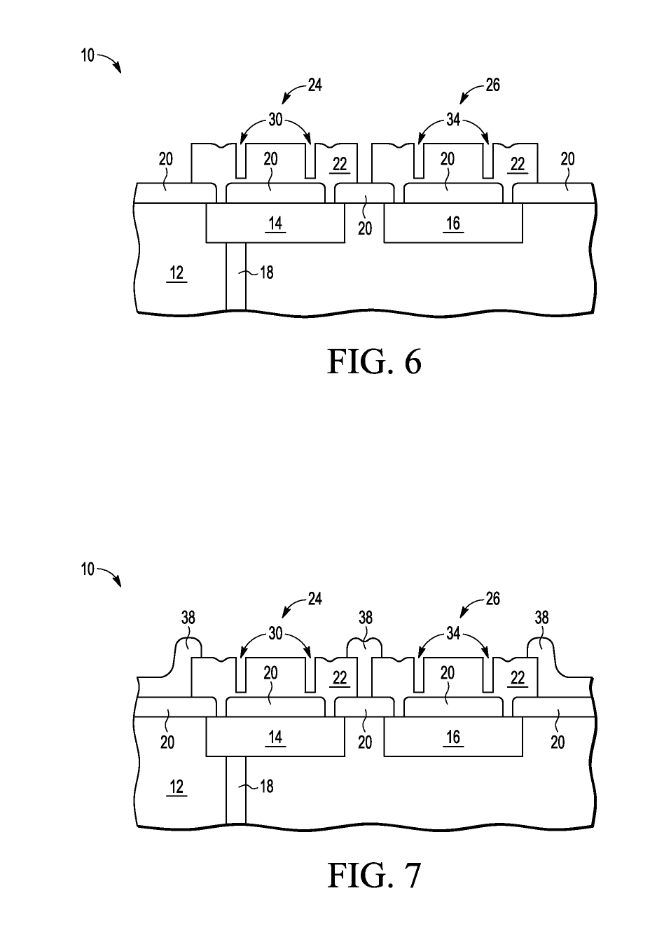

FIG. 6 illustrates, in a cross-sectional view, semiconductor structure 10 after removal of patterned photo resist layer 28.

FIG. 7 illustrates, in a cross-sectional view, semiconductor structure 10 after formation of a patterned passivation layer 38 formed over passivation layer 20 and bond pads 24 and 26. Passivation layer 38 exposes bond pad 24 and trench 30, and exposes bond pad 26 and trench 34. Portions of patterned passivation layer 38 are therefore formed between adjacent bond pads such as bond pads 24 and 26.

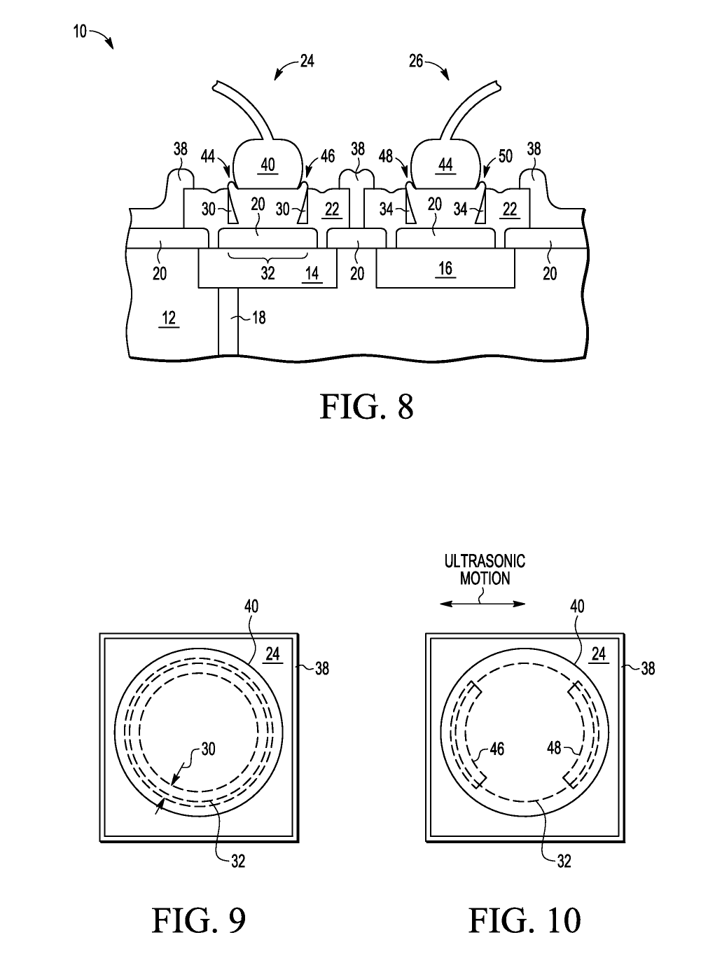

FIG. 8 illustrates, in a cross-sectional view, semiconductor structure 10 after wire bond connections are formed on the bond pads. Each wire bond connection includes a ball bond that is attached to a wire bond region of a corresponding bond pad. As illustrated in FIG. 8, ball bond 40 is attached to wire bond region 32 of bond pad 24 and ball bond 42 is attached to the wire bond region of bond pad 26. Note that upon attaching the wire bonds to the bond pads, a splash results. In the case of aluminum bond pads, these may be referred to as aluminum splashes. For example, splashes 44 and 46 are formed due to the deformation of bond pad 24 that occurs during attachment of ball bond 40. Splashes 44 and 46 correspond to deformed portions of bond pad 24 and are formed in the direction of the ultrasonic vibration of the wire bonder's transducer. Similarly, splashes 48 and 50 are formed due to the deformation of bond pad 26 that occurs during attachment of ball bond 42. Splashes 48 and 50 correspond to deformed portions of bond pad 26 which are formed in the direction of ultrasonic vibration of the wire bonder's transducer. In one embodiment, note that a material used to form the wire bond is harder (e.g. twice as hard) than a material used to form the bond pads. For example, in one embodiment, the wire bonds are copper and the bond pads are aluminum.

Note that splashes 44 and 46 expand into trench 30 and splashes 48 and 50 expand into trench 34. Therefore, note that trench 30 may be positioned and sized to contain at least a portion of splashes 44 and 46, and trench 34 may be positioned and sized to contain at least a portion of splashes 48 and 50. Also, as will be described in more detail below, each bond pad may include one or more trenches. The one or more trenches in each bond pad may be formed in an area where the splash will form when a wire bond is attached to a wire bond region of the bond pad. In one embodiment, the one or more trenches in each bond pad may have a volume large enough to contain at least 40% of the splash.

FIG. 9 illustrates a top down view of bond pad 24 of semiconductor structure 10 of FIG. 8 in accordance with one embodiment of the present invention in which trench 30 is a single trench. The perimeter of bond pad 24 is surrounded by passivation layer 38. Within bond pad 24, a solid circle labeled as 40 represents the perimeter of ball bond 40. The second dotted circle in from the perimeter of ball bond 40 represents wire bond region 32 of bond pad 24. The first and third dotted circles from the perimeter of ball bond 40 represent the inner and outer edges of trench 30. As can be seen in the embodiment of FIG. 9, trench 30 is formed at the perimeter of the wire bond region. Also, trench 30 is continuous around wire bond region 32.

FIG. 10 illustrates a top down view of bond pad 24 of semiconductor structure 10 of FIG. 8 in accordance with another embodiment of the present invention in which in place of a single trench 30, two trenches, trench 46 and 48, are formed. In this embodiment, openings 29 and 31 in photo resist 28 may correspond to trenches 46 and 48, respectively, rather than to opposite sides of trench 30. That is, rather than having a single continuous trench 30, multiple trenches may be used and positioned where the splash is formed. For example, trenches 46 and 48 may be positioned in accordance with the direction of ultrasonic vibration of the wire bonder's transducer. That is, the splashes may be formed in the direction of the vibration, therefore, trenches 46 and 48 may be formed perpendicular to this direction in order to capture the splash. Also, note that trenches 30, 46, and 48 may have different shapes. For example, they may be rectangular in shape rather than curved.

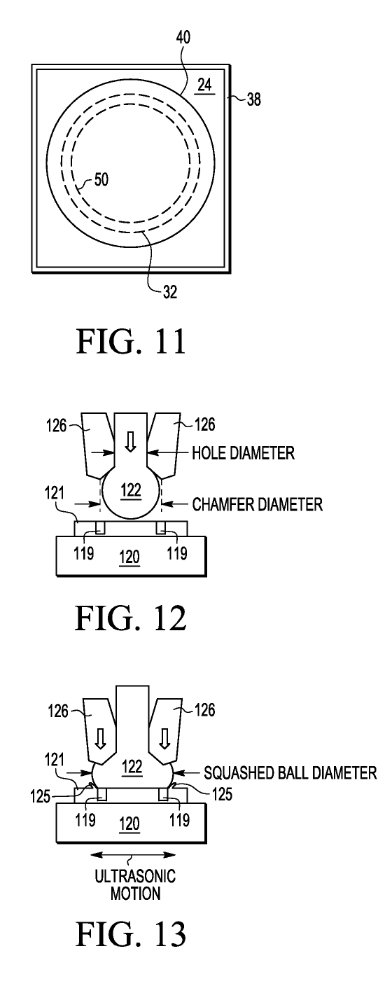

FIG. 11 illustrates a top down view of bond pad 24 of semiconductor structure 10 of FIG. 8 in accordance with another embodiment of the present invention in which in a trench may extend to the edge of bond pad 24, thus creating a thinner portion of bond pad 24 at a perimeter of bond pad 24. That is, the portion of bond pad 24 located within boundary 50 would be thicker than the portions of bond pad 24 located outside of boundary 50. The portions of bond pad 24 outside of boundary 50 would be etched with a partial etch, just as described in reference to trench 30, but it would extend to the edges of bond pad 24.

As will be described below, each of the trenches described above in reference to FIGS. 9-11 can be formed such that an inner edge (e.g. inner edge of trench 30, or trenches 46 and 48, or the trench extending from boundary 50) of the one or more trenches is positioned at or beyond an expected outer edge of a capillary chamfer region of ball bond 40. For example, FIGS. 12 and 13 illustrate a step-by-step overview of an example wire bonding sequence for bonding a copper wire bond to an aluminum bond pad. As shown in FIG. 12, the bonding process begins with a threaded capillary 126 that is positioned above bond pad 121 formed on a semiconductor structure 120. In particular, capillary 126 is threaded with a copper wire conductor and ball bond 122. In an example sequence, a copper wire conductor is inserted or threaded through a central opening in the capillary having a specified hole diameter, followed by formation of ball bond 122 at the end of the wire conductor, such as by using an electrical flame off (EFO) process to form a free air ball. In capillary 126, the free air ball portion is captured in the capillary's chamfer portion having a specified chamfer diameter.

As shown in FIG. 13, capillary 126 with copper wire conductor and ball bond 122 descends or moves down to the wire bond region (which may also be referred to as the bond site) on bond pad 121. By applying downward force from capillary 126 to bond pad 121 and structure 120, the ball bond 122 is deformed to form a squashed ball bond. In addition, the deformation of ball bond 122 leaves an impression deformity in ball bond 122 that corresponds to the shaped of the impressed chamfer. In the example, the depicted impression deforming is a v-shaped impression defined by a low point in the upper surface of the squashed ball bond.

Afterwards, the ball bonding process may include a specified combination of heat, pressure and ultrasonic energy to form an intermetallic connection or weld between ball bond 122 and bond pad 121. During this process, splashes 125 are formed. However, trench 119 operates to contain at least a portion of the splash. In one embodiment, ball 122 corresponds to ball 40, bond pad 121 to bond pad 24, trench 119 to trench 30, trenches 46 and 48, or the trench extending from boundary 50, and splashes 121 and 125 to splashes 44 and 46. Therefore, note that by forming trench 119 such that an inner edge of trench 119 is positioned at or beyond an expected outer edge of a capillary chamfer region of bond ball 122, trench 119 may be positioned to contain a sufficient amount of the splash. In this manner, passivation cracking may be reduced which typically occurs with the splashes when trench 119 is not present.

By now it should be appreciated that there has been provided a bond pad with partially etched trenches sized and positioned to capture at least a portion of any splashes formed during the wire bond process. Each bond pad may include a single trench or a plurality of trenches. In this manner, passivation cracking between the bond pads may be reduced, thus increasing yield.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Although the invention is described herein with reference to specific embodiments, various modifications and changes can be made without departing from the scope of the present invention as set forth in the claims below. For example, the trenches may have different configurations and shapes, as needed, to contain or reduce the splashes. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

The term “coupled,” as used herein, is not intended to be limited to a direct coupling or a mechanical coupling.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

The following are various embodiments of the present invention.

In accordance with one embodiment of the present invention, a method includes forming a conductive bond pad over a conductive structure in a last metal layer of an integrated circuit; and etching a trench around at least a portion of a perimeter of a wire bond region of the conductive bond pad, a portion of the conductive bond pad remains at the bottom of the trench to retain a conductive path between the wire bond pad region and the integrated circuit, and the trench is positioned and sized to contain at least a portion of a splash of the conductive bond pad when a wire bond is subsequently formed in the wire bond region. In a further embodiment, a material used to form the wire bond is harder than a material used to form the conductive bond pad. In another further embodiment, the trench is continuous around the perimeter of the wire bond region. In another further embodiment, the method includes etching a plurality of the trenches around the perimeter of the wire bond region, the trenches are positioned and sized to contain at least a portion of the splash of the conductive bond pad when the wire bond is subsequently formed in the wire bond region. In another further embodiment, the method includes patterning passivation material over a portion of the conductive structure before forming the conductive bond pad, the passivation material is configured so that a portion of the conductive bond pad is in direct contact with the conductive structure once the conductive bond pad is formed and before the trench is etched. In another further embodiment, a material used to form the conductive bond pad includes aluminum and a material used to form the wire bond includes copper. In another further embodiment, the trench is positioned in an area where the splash will form when the wire bond is subsequently formed in the wire bond region. In another further embodiment, a volume of the trench is large enough to contain at least 40 percent of the splash. In another further embodiment, an inner edge of the trench is positioned at or beyond an expected outer edge of a capillary chamfer region of the wire bond. In another further embodiment, a material used to form the wire bond is at least twice as hard as a material used to form the conductive bond pad.

In accordance with another embodiment of the present invention, a method includes receiving an integrated circuit that includes an external bond pad, the bond pad includes a trench around at least a portion of a wire bond region and only partially through the bond pad; and forming a wire ball bond in the wire bond region of the external bond pad, wherein a portion of the external bond pad is pushed into the trench as the ball bond is formed. In a further embodiment of the another embodiment, a material used to form the wire bond is harder than a material used to form the external bond pad. In another further embodiment of the another embodiment, the method further includes at least one of a group consisting of: the trench is continuous around the perimeter of the wire bond region, and a volume of the trench is large enough to contain at least 40 percent of the splash. In another further embodiment of the another embodiment, the bond pad includes a plurality of the trenches around the perimeter of the wire bond region, the trenches are positioned and sized to contain at least a portion of the splash of the conductive bond pad when the wire bond is formed in the wire bond region. In another further embodiment of the another embodiment, the bond pad includes a plurality of the trenches around the perimeter of the wire bond region. In another further embodiment of the another embodiment, an inner edge of the trench is positioned at or beyond an expected outer edge of a capillary chamfer region of the wire bond.

In yet another embodiment of the present invention, a semiconductor device includes an integrated circuit including an external bond pad, the external bond pad includes a trench around at least a portion of a perimeter of a wire bond region, the trench extends only partially through a thickness of the external bond pad; and a wire bond formed in the wire bond region, at least a portion of a splash of the external bond pad is contained in the trench. In a further embodiment of the yet another embodiment, an inner edge of the trench is positioned at or beyond an expected outer edge of a capillary chamfer region of the wire bond. In another further embodiment of the yet another embodiment, a volume of the trench is large enough to contain at least 40 percent of the splash. In another further embodiment of the yet another embodiment, a material used to form the wire bond is harder than a material used to form the external bond pad.

What is claimed is:

1. A method comprising:
forming a conductive bond pad over a conductive structure in a last metal layer of an integrated circuit; and
etching a trench around at least a portion of a perimeter of a wire bond region of the conductive bond pad, a portion of the conductive bond pad remains at the bottom of the trench to retain a conductive path between the wire bond pad region and the integrated circuit, and the trench is positioned and sized to contain at least a portion of a splash of the conductive bond pad when a wire bond is subsequently formed in the wire bond region.

2. The method of claim 1 wherein a material used to form the wire bond is harder than a material used to form the conductive bond pad.

3. The method of claim 1 wherein the trench is continuous around the perimeter of the wire bond region.

4. The method of claim 1 further comprising etching a plurality of the trenches around the perimeter of the wire bond region, the trenches are positioned and sized to contain at least a portion of the splash of the conductive bond pad when the wire bond is subsequently formed in the wire bond region.

5. The method of claim 1 further comprising:
patterning passivation material over a portion of the conductive structure before forming the conductive bond pad, the passivation material is configured so that a portion of the conductive bond pad is in direct contact with the conductive structure once the conductive bond pad is formed and before the trench is etched.

6. The method of claim 1 wherein a material used to form the conductive bond pad includes aluminum and a material used to form the wire bond includes copper.

7. The method of claim 1 wherein the trench is positioned in an area where the splash will form when the wire bond is subsequently formed in the wire bond region.

8. The method of claim 1 wherein a volume of the trench is large enough to contain at least 40 percent of the splash.

9. The method of claim 1 wherein an inner edge of the trench is positioned at or beyond an expected outer edge of a capillary chamfer region of the wire bond.

10. The method of claim 1 wherein a material used to form the wire bond is at least twice as hard as a material used to form the conductive bond pad.

11. A method comprising:
receiving an integrated circuit that includes an external bond pad, the bond pad includes a trench around at least a portion of a wire bond region and only partially through the bond pad; and
forming a wire ball bond in the wire bond region of the external bond pad, wherein a portion of the external bond pad is pushed into the trench as the ball bond is formed.

12. The method of claim 11 wherein a material used to form the wire bond is harder than a material used to form the external bond pad.

13. The method of claim 11 further comprising at least one of a group consisting of: the trench is continuous around the perimeter of the wire bond region, and a volume of the trench is large enough to contain at least 40 percent of the splash.

14. The method of claim 11 wherein the bond pad includes a plurality of the trenches around the perimeter of the wire bond region, the trenches are positioned and sized to contain at least a portion of the splash of the conductive bond pad when the wire bond is formed in the wire bond region.

15. The method of claim 11 wherein the bond pad includes a plurality of the trenches around the perimeter of the wire bond region.

16. The method of claim 11 wherein an inner edge of the trench is positioned at or beyond an expected outer edge of a capillary chamfer region of the wire bond.

17. A semiconductor device comprising:
an integrated circuit including an external bond pad, the external bond pad includes a trench around at least a portion of a perimeter of a wire bond region, the trench extends only partially through a thickness of the external bond pad; and
a wire bond formed in the wire bond region, at least a portion of a splash of the external bond pad is contained in the trench.

18. The device of claim 17 wherein an inner edge of the trench is positioned at or beyond an expected outer edge of a capillary chamfer region of the wire bond.

19. The device of claim 17 wherein a volume of the trench is large enough to contain at least 40 percent of the splash.

20. The device of claim 17 wherein a material used to form the wire bond is harder than a material used to form the external bond pad.
